(19) United States
(12) Patent Application Publication
(10) Pub. No.: US 2014/0174503 A1
(43) Pub. Date: Jun. 26, 2014

(54) ENERGY CONVERTOR/CONCENTRATOR SYSTEM

(71) Applicants: Andre Broessel, Barcelona (ES); Michael Puetz, Duesseldorf (DE)

(72) Inventors: Andre Broessel, Barcelona (ES); Michael Puetz, Duesseldorf (DE)

(21) Appl. No.: 13/984,323

(22) PCT Filed: Feb. 10, 2012
(86) PCT No.: PCT/EP12/52323

§ 371 Date: Mar. 10, 2014

(30) Foreign Application Priority Data
Feb. 11, 2011 (DE) 10 2011 000 667.2
May 13, 2011 (DE) 10 2011 050 332.3

(51) Int. Cl. H01L 31/0525; F24J 2/38; H01L 31/052

(52) U.S. Cl. CPC H01L 31/058; H01L 31/0522; F24J 2/38
USPC 136/248; 136/246; 126/600

(57) ABSTRACT

The invention relates to an energy convertor/concentrator system (4) for directly converting solar energy into electric and/or thermal energy, containing at least one energy convertor. The aim of the invention is to provide at least one concentrating optic (5) for concentrating incident solar light (8) onto an absorber module (7).

This invention relates to an energy converter/concentrator system for converting solar energy to electrical and/or thermal energy, comprising at least one energy converter.

### PRIOR ART

Energy converter modules are well-known in the prior art. A variety of approaches exist for achieving higher efficiencies, both in the area of solar thermal energy and also with photovoltaics. In both systems, both a concentrated incident angle of radiation as well as a directed incident angle of radiation are advantageous in terms of increasing efficiency. To this end, for example, optical concentrators such as lenses and mirrors having dual-axis tracking systems are used.

The fundamental goal is to achieve the highest possible is energy yield and low production costs. Studies involving tracking systems, for example, show a yield increase of 30% or more in photovoltaics by using the directional control of light and the orientation of the modules perpendicular to the sun. With respect to integration in buildings, however, it is very difficult to implement tracking, particularly in the area of facades, with conventional collector modules by tilting the orientation, the azimuth, and altitude for the sun position, and such tracking is generally employed in large-scale exterior settings for power plants, both in solar-thermal and photovoltaic power generation, as disclosed, for example, in WO2007093422 [US 2009/0126794].

Significant losses without tracking systems occur especially with vertical orientation angles, whereby, for example, an optimized orientation angle averaging 35° has been calculated for latitudes of about 54° to 47° north, and longitudes of 6° to 12° east. Classic tracking systems (both single-axis and dual-axis systems) are distinguished by the fact that they can support as many collector modules as possible. The size of the collector modules governs the pivot area required for this purpose, possible mutual shading, and the ultimate overall area requirement.

In addition, control requirements in terms of precision and stability are very stringent and cost-intensive in tracking systems for collector modules, in particular, concentrator modules. Static parameters, such as the calculation of wind and snow loads, determine dimensions and limit the systems accordingly. Using available technologies, it is technically extremely difficult to provide a low-maintenance tracking system, that is, one that is not affected by weather.

The photovoltaic sector, on the other hand, seeks a cost reduction for the semiconductor surfaces, as well as the silicon, and achievable higher efficiencies. This is primarily done using Fresnel lenses functioning as concentrator optics, while the high-sensitivity solar cells are maintained at a stable operating temperature with heat sinks or IR hologram structures.

Analogous approaches to those in the photovoltaic sector are employed with solar thermal technology for generating energy from heat. The collectors reach temperatures ranging up to 450° Celsius and higher, and use corresponding heat-exchange media to directly utilize or transfer the heat.

When integrated into buildings, absorber modules in the form of flat collectors or vacuum-tube collectors are employed, for example, for heating nonpotable water. Working temperatures can be reached here that range between approximately 40° and 130° Celsius. Here again, the tilt angle is one factor for enhancing efficiencies, and thus flat collectors in most systems, for example, cannot be oriented horizontally.

Solar-thermal power plants, for example, employ parabolic troughs, Fresnel lens collectors, heliostats in tower-type power plants, and parabolic mirrors with single-axis or dual-axis tracking for concentrating in vacuum tube collectors, or special receivers. A disadvantage of the known systems with reflective is surfaces is their high maintenance costs due to the fact that the surfaces are susceptible to scratches that thus result in aberrations.

It must be noted that no cost-effective solutions have as yet been achieved for tracking. In general, for any type of semiconductor technology and thermal heat conversion, the basic principle and theory still applies whereby an optimally focused incident angle of radiation achieves the greatest efficiency.

### OBJECT

The object of this invention is therefore is to overcome the disadvantages of the described prior art, and to provide an energy converter/concentrator system, an energy converter, as well as an optically concentrated tracking function that by simple and cost-effective means enables the efficiency of the energy conversion system to be improved, and provides a means of more closely approaching an increase in efficiency without using the known tracking systems and concentrator designs.

### SOLUTION OF THE OBJECT

The object is achieved by the energy converter/concentrator system of claim 1, the concentrator optics or the concentrator system of claim 3, and the energy conversion module of claims 12 and 20. The remaining dependent claims show advantageous developments.

An energy converter/concentrator system is provided according to the invention for directly converting solar radiation into electrical and/or thermal energy, which system comprises at least one concentrating optic, and at least one solar cell and/or one absorber module (energy converter module).

The arrangement according to the invention comprising a module concentrating or converting optic to energy, hereafter also identified as photovoltaics module and/or absorber module, achieves an increased overall efficiency versus the prior art relative to conventional collectors, in particular, flat collectors, that include an optionally provided tracking system (also identified as trackers), where the spacing between the concentrating optic and the energy converter modules depends on the design structure being considered, and can vary from less than one millimeter to a few meters. However, the spacing preferably ranges between 1 mm and 10 m, in particular, between 0.1 mm and 50 mm, or between 10 cm and 500 cm.

It may be sufficient in many cases if the energy converter module is of stationary design. For example, a cup-shaped module support can be provided on the side of the optics opposite the sunlight, which module can be fitted with a plurality of absorber modules. However, this can just as well be an absorber panel. Many possible approaches are conceivable here and fall within the scope of the invention.

In one preferred embodiment, tracking is nevertheless provided. For example, in one preferred embodiment the at least one energy converter module can be, but does not have to be, pivotable. The concentrating optic is configured here in such a way that optimal tracking of the incident radiation is achieved by focusing, and the radiation is emitted in concentrated form with emergent radiation directed onto the energy converter module that has a configuration that is shaped for the optic.

In terms of design, multiple approaches can be conceived for tracking the energy converter module, all of which approaches fall within the scope of the invention. It is possible, for example, to mount the energy converter module on a rig whose ends are pivotally mounted on the axis of the optic. The rig then pivots around the optic so that the energy converter module can still be adjusted along the rig in accordance with the focus of the incident sunlight. However, a robot is also in fact possible that aligns the energy converter module with the focus of the optic.

Any design is possible for the concentrating optic, whether as a tube, ellipse, or the like. The preferred approach is a concentrating optic that is a transparent sphere composed of glass, such as, for example, soda-lime glass, lead glass, borosilicate glass, and optical glass, or organic glass such as resins and polymers, and other synthetic materials. The materials may be combined, or only one may be used.

In another advantageous embodiment, the outside of the transparent sphere includes a selective filter in the hemisphere facing the sun, which filter can be applied, for example, in the form of surface plasmons. As a result, the total sunlight, that is, the direct and indirect incident sunlight, can be alternately amplified.

The critical factor is the refractive index n that must not exceed a factor of 2. The preferred refractive index is between 1 and 2n.

In another advantageous embodiment, the sphere is a transparent hollow sphere that is filled with liquid or gel, appropriate liquids being water, distilled water, ethanol, glycol, or other chemical liquids. Only one liquid may be used, or they can be combined. The hollow sphere can preferably be made in such a way that it is composed of one or more sections. Possible materials include soda-lime glass, lead glass, borosilicate glass, and optical glass, or organic glass such as resins and polymers, and other synthetic materials. A preferred combination of at least one transparent sphere, or a hollow sphere that is filled with at least one liquid and/or gel as the concentrating optic that concentrates the incident sunlight and thus increases the intensity of the emergent radiation, allows the incident radiation on the photovoltaic module and/or absorber module to be optimized, where the spacing from the focal plane can be advantageously adjusted for the photovoltaic module and/or absorber module.

In another advantageous embodiment, the hollow sphere includes at least one selective filter, this time on the inside, that is, the side facing the absorber module. The filter is configured so as to be transparent to light from an angular field range from which concentrated sunlight enters, while light outside this angular field range is reflected. The advantage here is that the concentration of light is increased in this arrangement since the selective filter blocks entering light from re-emerging, and furthermore reflects the light generated in the solar cell by recombination so that it can be utilized by the photovoltaic module and/or absorber module, which filter could be a Rugate and/or edge filter, or surface plasmons applied as metallic nanoparticles, or 2D or 3D photonic crystals in the form of normal and/or inverted opals. Any site, however, can be selected for the filter between the photovoltaic module and/or absorber module and concentrating optic.

It is advantageous to associate at least one valve with the liquid-filled hollow sphere for the purpose of supplying the liquid, or for control with or without feedback. The valve is advantageously provided, for example, on the top side of the azimuth axis so as to regulate the generation of air.

In the case of a dimensional size that is, for example, difficult to implement, the energy converter/concentrator system can also be provided with a supporting structure in the form of an exterior rod-type structure—for example, one composed of steel—that enhances overall stability.

The object of this invention is also to more closely approach the maximum efficiency for a solar energy converter system by, first of all, enabling the optical tracking to be concentrated, and, secondly, by enabling the energy converter modules to be oriented on different axes. The combination according to the invention enables tracking to be provided that can be easily achieved using conventional energy converter modules.

Provision is essentially made in a preferred variant whereby sunlight is converted directly into electrical energy, and at least one concentrating optic, which is provided on at least one cover panel, comprises at least one hemispherical body or a section thereof including at least one attached solar cell, such as for is example silicon solar cells or thin-film solar cells, or III-V solar cells (multiple stacked cells), or transparent or organic solar cells, a mounting frame, attachment elements, at least one actuator, and a base plate.

The concentrating optic, here a transparent or hollow sphere filled with liquid, is associated with the transparent cover panel, composed here of glass, plexiglass or acrylic and preferably clamped in place—this being made in such a way that partial surfaces penetrate the side of the cover panel facing the incident radiation. This arrangement allows the angle of the incident radiation to be increased, thereby ensuring that the solar cells are advantageously fully illuminated by light focused by the concentrating optic.

In another advantageous embodiment of the system according to the invention, it is also possible, however, for at least one joining layer to be provided at least in certain regions between the cover panel and the transparent sphere or the transparent hollow sphere. This can preferably involve a laminating layer of adhesive layer. The selected joining layer here is preferably from the group ethylene vinyl acetate, polyvinyl butyral, acrylic-based adhesive layer or hot-melt adhesive, such as polyamides, polyethylenes, amorphous poly-alpha-olefins, polyester elastomers, polyurethane elastomers, copolyamide elastomers, vinylpyrrolidon/vinyl acetate copolymers or polyester, polyurethane, epoxide, silicon and vinyl ester resins.

On the other hand, the cover panel according to the invention can also be made such that the transparent sphere is part of this body and is preferably composed of the same material. In another preferred variant of the cover panel, which is built up here of multiple layers, solar cells are attached to the remaining regions or surrounding edge regions of the aperture area of the spherical surface. By way of example, the layered structure for the incident radiation is as follows: glass-ethylene vinyl acetate/polyvinyl acetate-solar cells-EVA/PVB-Tedlar (polyvinyl fluoride)-plastic/aluminum-Tedlar. The layers can be joined to each other in any order.

In another advantageous embodiment, the cover panel is provided on the front side, that is, in front of the side facing the incident radiation of the transparent sphere, and is held by the mounting frame. This enables smooth, flat surfaces to be produced on the module, and allows an independently advantageous arrangement of the concentrating optic to be produced inside the module. The concentrating optic here is preferably retained by an adjustable attachment element that can be moved or pivoted about at least one axis.

The at least one hemispherical body, here preferably a section of a sphere, is held by an adjustable attachment element, supports the at least one movable cell and parts of its circuitry, can be aligned at least in one axis, and is hereafter identified as a photovoltaic module. Movement of the at least one cell along the hemispherical body preferably is within a radius of between 1° and 180°, in particular, preferably between 1° and 100°. The especially preferred approach is for the photovoltaic module and attachment element to be movable and/or pivotable in all three x, y, and z axes. A conceivable approach is to have actuators, such as, for example, cylinders or electromechanical actuators to move the attachment elements and the photovoltaic module.

Axial movements are preferably controlled by at least one actuator and a controller that has data on the position of the sun. This arrangement has the advantage that the photovoltaic module can be optimally adjusted independently of the sun-oriented azimuth to the altitude of the sun and for the configuration, such as in terms of inclination of a facade, and thus in terms of area can be designed for the minimum required by the annual paths of the sun for an undefined location.

According to the invention, the photovoltaic module also functions to adjust the focal plane that constitutes the spacing from the concentrating optic. What is preferred is a concentration of between 6 times and 20,000 times, in particular, between 50 times and 1000 times.

In another variant, a conventional secondary concentrator is associated with the photovoltaic module on the side facing the sun. Particularly when, for example, multi-stacked cells and a concentration of >50 are used, this functions first to control possible tilting of the module and second to supply the cell types that have both homogeneous and also focus-specific requirements.

In another embodiment according to the invention of the photovoltaic module, this module can also be made so as to surround half or part of the concentrating optic. This would have the advantage of eliminating the need for adjustment, while the larger area could also be fitted with cells, although this would not have to be done.

In another advantageous embodiment, the photovoltaic module can also be of cylindrical shape. This shape can be a section of a tube, or a flat, flexible cut area. This would in this case again be a section that is optimized for the path of the sun.

The hemispherical body preferably functions as a heat sink to lower the operating temperature of the solar cells, thus stabilizing the efficiency and holding it constant.

Appropriate materials for the hemispherical, cylindrical, or curved body are composites, plexiglass, polymethyl methacrylate (PMMA), acrylic glass, other synthetic materials and glass, as well as steel, galvanized steel, copper, stainless steel, aluminum, and/or other metals. The materials can be combined, or only one can be used. Implementations of the above-described constructive designs that are effected in certain sections also fall within the scope of the invention.

A series circuit connection is preferably provided that is composed of any number of concentrating optics and photovoltaic modules set a certain spacing apart, the at least one single-axis motion being associated with the photovoltaic module supported by the mounting frame and the attachment elements. What is especially preferred is a dual-axis motion of the photovoltaic module that provides precise tracking.

According to the invention, the attachment elements can be part of the mounting frame. They can be of any form. They can, for example, include screw-type elements that allow the module to be adjusted from the outside, or can be made in plug-in fashion so as to provide a mechanical connection of the module to other modules effecting the series circuit connection, the attachment elements according to the invention being primarily intended for the tracking function of the photovoltaic modules relative to each other.

According to the invention, the attachment elements can also be designed for electrical lead-through, preferably, in moisture-proof and/or gas-tight form, and/or as a ventilation opening. This electrical lead-through can be connected inside, for example, by a wire to the solar cells, and then functions to provide the electrical wiring of the solar cells to external equipment or to effect the series circuit connection.

According to the invention, the mounting frame of the module delimits the space containing the solar cells, identified hereafter as the interior space, from the exterior space. The mounting frame identifies the entire collective of all components that connect cover panel and base plate at their edges.

The frame preferably furthermore functions to mount the actuators, controller, and devices that support the operation of the photovoltaic module, whether individually or in combination with other modules. For example, a bracket can be screwed on or welded on by means of which the photovoltaic module can be mounted and/or adjusted. The bracket can be designed to enable the modules to be attached, for example, by hooking, screwing, and/or plugging them in. The bracket can preferably include electrically conductive components that, for example, allow the photovoltaic is module to be grounded.

Possible appropriate materials for the frame and the attachment elements include composites, plexiglass, polymethyl methacrylate (PMMA), acrylic glass, other synthetic materials, and glass, as well as steel, galvanized steel, stainless steel, aluminum, and/or other metals.

In another advantageous embodiment of the frame, the frame can be composed of hollow structural sections for purposes of thermal and sound insulation, or be provided and/or filled with insulating material to control heat and sound in the interior space. Appropriate insulating materials preferably include foamed plastics such as polystyrene and polyurethane.

In another conceivable approach according to the invention, parts of the frame are designed so as that a reflective surface is provided in the interior space, which surface is intended, for example, to utilize the surrounding edge region of the aperture surface of the concentrating optic, thereby utilizing a certain level of scattering or diffusivity in the bandwidth of spectral distribution of the sunlight, and providing additional concentration of the radiation. The materials can be combined, or they can be used alone. Sealing compounds, such as, for example, elastic silicon or technical adhesives, can also be accommodated here to effect sealing and for any stresses due to temperature.

In another advantageous embodiment, the combination of cover panel, base plate, and mounting frame enables large modules to be produced, thereby allowing, for example, sizes to be produced that are technically difficult to make. A plurality of spacers is incorporated for this purpose in order to support longitudinal extensions. These are advantageously provided on the base plate. The base plate can additionally function to enable the equipment to be attached that supports the module as a single unit or in combined form. The base plate also functions to provide thermal and sound insulation, although it does not have to do this.

In another preferred embodiment, at least one control device is mounted on the base plate extending into the interior space. Examples of possible control devices include, for example, semiconductors such as diodes, or even sensors. These are provided according to the invention with a wire so as to allow control to be provided.

Possible appropriate materials for the base plate include composites, plexiglass, polymethyl methacrylate (PMMA), acrylic glass, other synthetic materials and glass, as well as steel, galvanized steel, copper, stainless steel, aluminum, and/or other metals. The materials can be combined, or only one can be used.

Provision is essentially made in another variant according to the invention, whereby the sunlight is converted directly into thermal energy, the structural design and the arrangement of the at least one concentrating optic, cover panel, attachment elements, and mounting frame being produced as in the above-described configuration, while here the at least one hemispherical body is provided in the form of an absorber module and includes at least one heat-exchange system.

The absorber module is preferably composed of an absorption panel and a heat-exchange system that rests on the absorption panel. The absorption panel, composed here, for example, of steel, aluminum, copper, or synthetic material, is—or at least the side facing concentrating optic is—a preferred section of a sphere. On the other hand, the absorption panel can also be made such that the panel is of cylindrical shape, that is, includes a section of a tube or a flat flexible cut area. The absorption panel is preferably provided with a coating, such as Tinox, Ethaplus, or other known absorber coatings.

In another advantageous embodiment of the hemispherical absorption panel, this panel can also be made so as to surround half the concentrating optic and allow for a series circuit connection.

In another advantageous embodiment of the invention, the absorption panel is composed of glass or sintered materials, and allows for higher temperatures for the heat-exchange system. Another possible approach here involves a vacuum method and an embodiment such as, for example, that known in absorber collectors. The heat-exchange system preferably consists of at least one tube or tube system, and is connected to the absorption panel.

According to the invention, the absorber panel, for example, can be hollow and surround the tube system in order, for example, to embed an insulating material. The tube system is preferably of meandering shape and is attached to the absorption panel by a weld or an adherence-type connection. Possible adherence-type connections include, for example, soldering and welding agents, but also adhesives. The tube system is preferably associated with the sun-oriented side, but does not have to be. In another advantageous embodiment, the tube system, as well as a harp or a fractal system, can be provided so as to optimize flows or pressure losses.

The attachment elements according to the invention can be part of the mounting frame, and in terms of a lead-through for the heat-exchange system be provided preferably with a flexible and/or thermally insulated connecting opening, and/or in terms of an electrical lead-through for a sensor to measure temperature or pressure.

Another variant of the invention essentially provides an approach whereby sunlight is converted directly into thermal and/or electrical energy, the concentrating optic being of a design analogous to the above-described arrangements and including at least one single-axis decouplable tracking system for the absorber and/or photovoltaic module.

This arrangement allows the emergent focus to be concentrated independently of the spatial environment. The absorber and/or photovoltaic modules according to the invention, hereafter identified as modules, are designed in such a way that the preferred hemispherical body as in the above description here includes an advantageous sectional region in the course of the vertical for the altitude of the sun that tracks the azimuth axis, and is attached to a mount that is controlled by an actuator, as in the above-described arrangements. The mount refers to the totality of all components that connect and move the modules in the above-described manner. The mount can be made so as to surround the modules, with the result that a gap extends up to the concentrating optic in the form of a segment of a circle. The rotational axis of the mount according to the invention for tracking the azimuth in an advantageous embodiment can be oriented vertically as desired in the center axis of the concentrating optic, but does not have to be. Similarly, a retaining mount is provided whose pivot axis is transferred out and that in another advantageous arrangement is located vertically resting above or below the concentrating optic. The mount here is a circular segment of 360°. What is preferred is a circular segment between 0° and 250°. This would have the advantage that, for example, the entire course of the sun from sunrise to sunset can be utilized in very sunny regions. What is especially preferred is a circular segment between 0° and 180° that is provided, for example, inside a building, that is, the side opposite the incident radiation.

According to the invention, the offset of the module, that is, the section of the hemispherical body, can be extended as desired in vertical pivot axis of the mount, for example, linearly. The mount thus functions according to the invention to regulate interior heights.

The mount can be composed either wholly or in part of hollow sections that according to the invention support the tubes and/or electrical cables of the modules. In particular, the mount is designed so as to enable the modules to be pluggable and/or movable, and thus advantageously have openings by which other components can be provided, such as, for example, system brackets. In another variant according to the invention, the mount provides an additional actuator that regulates the adjustment for the altitude of the sun.

Appropriate materials for the mount include composites, plexiglass, polymethyl methacrylate (PMMA), acrylic glass, other synthetic materials and glass, as well as steel, galvanized steel, copper, stainless steel, aluminum, and/or other metals. The materials can be combined, or they can be used alone.

In another preferred embodiment, the module comprises a tubular receiver for high-temperature heat. The tubular receiver can be composed of a plurality of metal tubes that are either empty or contain heat-exchange media, where possible the heat-exchange media include water, thermal oil, fused salts, and metal, and this functions to integrate additional components, for example, to effect interconnection. In another advantageous embodiment, the module comprises a volumetric pressure receiver for high-temperature heat. In another preferred embodiment, the module comprises a Stirling engine to effect conversion to electrical energy.

All exemplary applications described here can be combined in any way, thereby enabling hybrid conversion of energy to be effected as a function of requirements and location. The described invention has the following advantages over the prior art:
The claimed invention enables a concentrated focusing of light to be precisely controlled with the arrangement at any tilt angle, with the result that an advantageous incident angle of radiation impinges on the photovoltaic/absorber module.
The claimed energy converter/concentrator system provides tracking in the interior space of buildings.
The claimed concentrating optic can be decoupled from the tracking system that supports the photovoltaic/absorber module.
The claimed photovoltaic/absorber module can be produced cost-effectively and flexibly.
The claimed photovoltaic module can yield savings in terms of expensive semiconductors as compared with PV modules known in the art, due to the added benefit of optical tracking with the same efficiency.
The energy converter/concentrator system allows for less restriction in terms of building integration since inclination losses are reduced.
The claimed photovoltaic/absorber module does not require any supplementary expensive mounting systems to effect tilt orientation.
The claimed concentrating optic arrangement is flexible and of compact dimensional size, and can thus be designed for individual performance requirements.
The claimed energy converter/concentrator system is more efficient than known installations of the prior art for relatively large structures requiring a smaller footprint since, for example, mutual shading of modules is less important.
The cost of tracking systems for installations can be reduced as compared with installations known in the art.
The claimed energy converter/concentrator system is low-maintenance, and, for example, less fragile than known reflective surfaces of the prior art.
The claimed concentrating optic can be flexibly adjusted and can concentrate up to a geometrical factor of several thousands.
The claimed selective filter provides the concentration of direct and indirect (diffuse) light.

### DESCRIPTION OF THE FIGURES

The invention is described in more detail below with reverence to the following figures; however this description is not intended to restrict the invention to the specific embodiments shown here. Identical and similar reference numerals are used to refer to identical and similar elements.

FIG. 1 shows in simplified fashion the paths of the sun at, by way of example, latitudes A and B.

FIG. 2 is a schematic diagram of an energy converter/concentrator system.

FIG. 3 is a part-sectional schematic view through an energy converter/concentrator system according to the invention.

FIG. 4 is a schematic view of couplings for tracking the energy converter/concentrator system according to the invention.

FIG. 5 shows simplified examples of the concentrating optic.

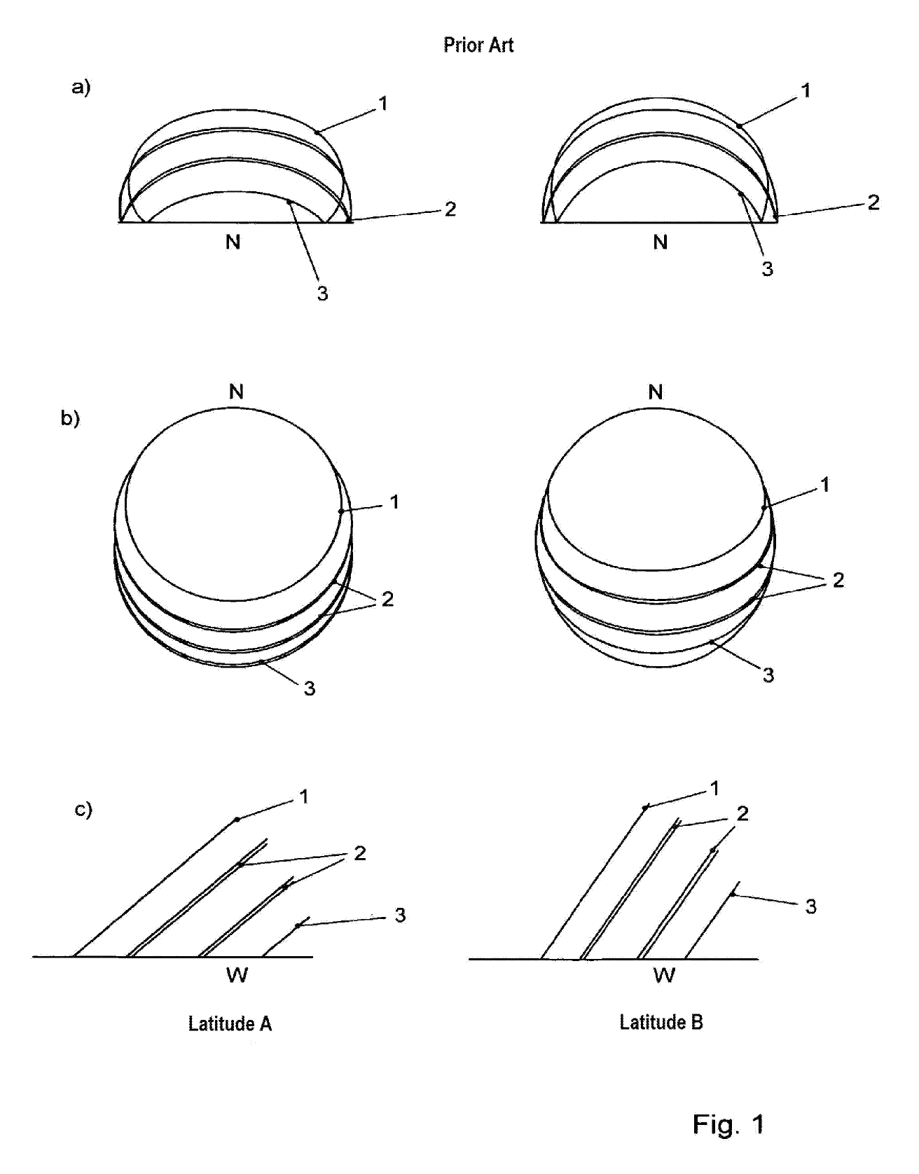

FIG. 1a) illustrates the calculation of solar-position diagrams as known from the prior art, which here schematically illustrate, by way of example, the coordinates for the paths of the sun for locations at latitude A relative to latitude B at the same longitude. Shown here are the positions of the sun at its highest point 1 as in June, middle point 2, and lowest point 3 as in December. The view proceeds from north to south. FIG. 1b) is the view from zenith. FIG. 1c) is the view from the west.

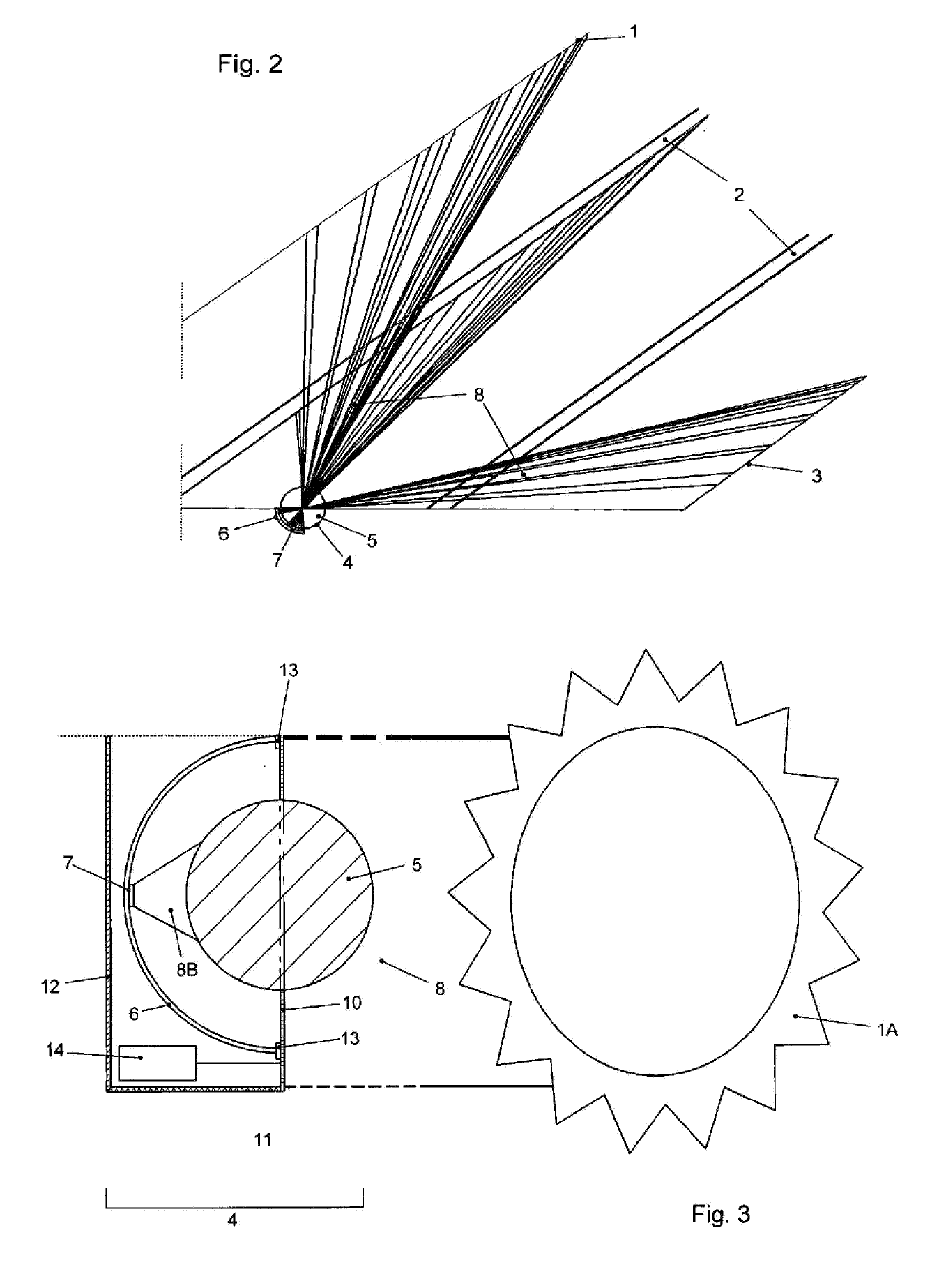

FIG. 2 is a schematic diagram of a variant according to the invention. The location-specific sun positions (FIG. 1), the highest 1, the middle 2, and the lowest 3, fall as sunlight on the energy converter/concentrator system 4. The energy converter/concentrator system 4 includes a concentrating element, in this case a transparent sphere (spherical lens) 5, a hemispherical absorber support 6, and an absorber module 7. The sunlight 8 that is emitted within the path of the sun positions, here shown in simplified form as rays of a conical beam, is focused by spherical lens 5 so that it strikes the absorber module 7 as light that is focused and directed, the module being supported by the absorber support 6.

FIG. 3 schematically illustrates parts of a variant according to the invention based on directly converting solar radiation into electrical energy. Direct sunlight emitted by the sun 1A and indirect (diffuse) sunlight 8 fall on the energy converter/concentrator system 4. The energy converter/concentrator system 4, in this case a photovoltaic concentrator system, includes the transparent spherical lens 5, the energy converter module/absorber module 6, the solar cell 7, a cover panel 10, a mounting frame 11, a base plate 12, attachment elements 13, and actuators 14.

Light from the sun 1A that is at a direct incident angle of radiation is focused by the spherical lens 5 so as to strike as light on the pivotable solar cell 7 supported by the pivotable energy converter module/absorber module 6.

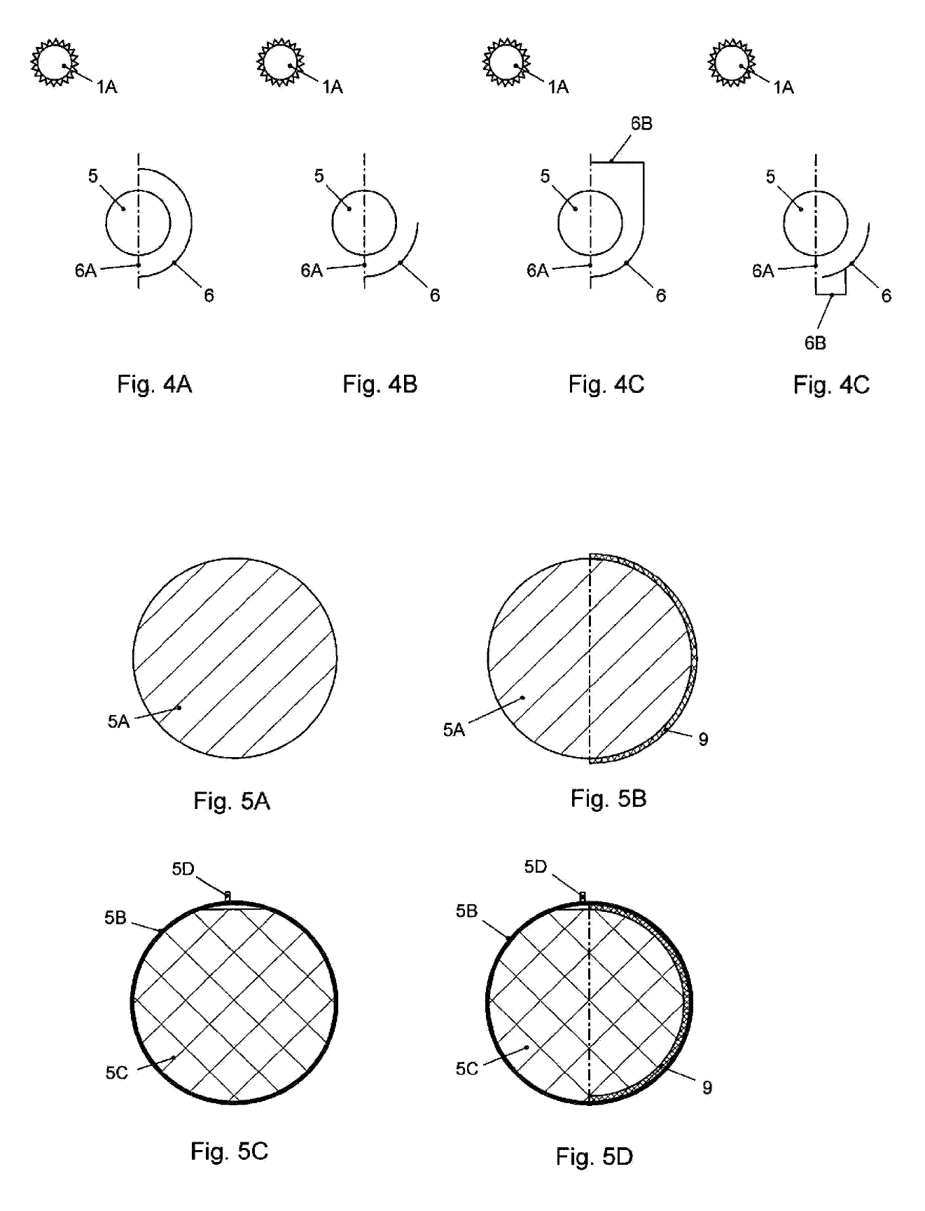

FIG. 4 schematically shows examples A, B, C, and D for coupling the concentrating optic and the tracking for the energy converter module/absorber module. FIG. 4A is a view of the spherical lens 5 and energy converter module/absorber module 6 when rotationally oriented on a center axis 6A with the sun 1A. In addition, FIG. 4A shows the energy converter module/absorber module 6 that surrounds half of the spherical lens 5, thereby allowing tracking to be both above and below the spherical lens 5.

FIG. 4B illustrates that the tracking for the energy converter module/absorber module 6 is connected under the spherical lens 5 to the center axis 6A. In this case, the energy converter module/absorber module 6 only needs to surround a quarter of the spherical lens 5.

FIG. 4C shows a variant in which the energy converter module/absorber module 6 is connected to the center axis 6A by a module support 6B. This module support 6b is above the spherical lens 5, whereas it is below the spherical lens 5 in FIG. 4D.

FIG. 5 illustrates simplified examples A, B, C, and D of the geometry of implementation for the spherical lens 5. FIG. 5A is shows a transparent spherical lens 5A. FIG. 5B shows a transparent spherical lens 5A, with a selective filter 9 on outside of half of the lens. FIG. 5C illustrates a transparent sphere 5B provided with a transparent filler 5C (either liquid or gel). In addition, FIG. 5C illustrates that a valve 5D for control purposes is associated with the upper part of spherical lens 5B. FIG. 5D shows the arrangement of the previous figures—in this case, however, a selective filter 9 is provided on the inside of the transparent sphere 5B.

1. An energy converter/concentrator system for directly converting solar energy to electrical and/or thermal energy comprising:
at least one energy converter;
at least one concentrating optic for concentrating incident sunlight onto a solar cell or onto an absorber module;
at least one tracking system that is controlled to receive concentrated sunlight moving with the course of the sun and that is associated with the module; and
a support carrying the module and pivotal about the optic such that the module is adjustable with respect to the focal-point travel or sun height.

2. (canceled)

3. The system according to claim 1, wherein the absorber module is mounted on the side of the at least one concentrating optic opposite the incident sunlight.

4. The system according to claim 1, wherein the at least one tracking system comprises a hemispherical absorber support with which the at least one optic is associated on the side of the incident sunlight and that partially surrounds the at least one concentrating optic.

5. The system according to claim 1, wherein the at least one concentrating optic is a transparent sphere or a transparent hollow sphere.

6. The system according to claim 5, wherein the transparent or hollow sphere includes a selective filter.

7. The system according to claim 5, wherein the sphere is composed of
soda-lime glass or lead glass or borosilicate glass or optical glass;
organic glass consisting of resins or polymers, or
a combination thereof,
wherein the hollow sphere comprises at least one part.

8. The system according to claim 5, wherein the transparent hollow sphere contains a liquid or a gel that contains
water or ethanol or glycol, or
gel, or
a combination thereof,
or is composed thereof.

9. The system according to claim 5, wherein the refractive index n of the transparent sphere, or of the liquid-filled and/or gel-filled hollow sphere, has a value of 0.35 n up to 3.90 n.

10. The system according to claim 1, further comprising:
at least one valve at least on the optic.

11. The system according to claim 1, wherein the at least one absorber module is a solar cell.

12. A photovoltaic concentrator system or photovoltaic module for directly converting solar energy into electrical energy, the system comprising:
at least one solar cell;
at least one concentrating optic;
at least one mounting frame, at least one base plate;
at least one tracking system that is controlled to receive the sunlight moving with the course of the sun and that has
at least one solar cell,
one actuator,
attachment elements,
a hemispherical absorber support associated with at least one solar cell on the side of the incident sunlight and partially surrounding the at least one concentrating optic; and
a support carrying the module and pivotal about the optic such that the module is adjustable with respect to the focal-point travel or sun height.

13. (canceled)

14. The photovoltaic concentrator system or photovoltaic module according to claim 12, wherein the at least one concentrating optic is a transparent sphere or a transparent liquid- and/or gel-filled hollow sphere and is composed of
soda-lime glass or lead glass or borosilicate glass or optical glass;
organic glass comprised of resins or polymers, or
a combination thereof,
wherein the hollow sphere contains
water or ethanol or glycol, or
gel, or
a combination thereof,
or is composed thereof.

15. The photovoltaic concentrator system or photovoltaic module according to claim 1, wherein the at least one concentrating optic is provided in an interior space of the at least one mounting frame, the at least one cover panel, and the at least one base plate.

16. The photovoltaic concentrator system or photovoltaic module according to claim 1, wherein the hemispherical absorber support and the at least one solar cell are pivotable by at least one actuator and attachment element.

17. The photovoltaic concentrator system or photovoltaic module according to claim 1, wherein the at least one hemispherical absorber support is a heat sink.

18. The photovoltaic concentrator system or photovoltaic module according to claim 1, wherein the mounting frame comprises at least one reflective surface on the inside, or is composed thereof.

19. The photovoltaic concentrator system or photovoltaic module according to claim 1, wherein multiple concentrating optics and/or multiple hemispherical absorber supports are associated with the at least one solar cell, one before the other, one behind the other, and/or adjacent each other.

20. An absorber concentrator system or absorber module for directly converting solar energy to thermal energy, the system comprising:
at least one absorber panel,
at least one concentrating optic,
at least one cover panel,
at least one mounting frame,
at least one base plate, and
at least one tracking system moving with the course of the sun to receive sunlight in a directed fashion, wherein the at least one tracking system is associated with the at least one absorption panel.

21. The absorber concentrator system or absorber module according to claim 20, wherein the at least one tracking system comprises a hemispherical absorber support with which at least one absorption panel is associated with the side of the incident sunlight, which panel at least partially surrounds the at least one concentrating optic.

22. The absorber concentrator system or absorber module according to claim 21, wherein the absorption panel comprises at least one heat-exchange system with a heat transfer fluid, or is composed thereof.

23. The absorber concentrator system or absorber module according to claim 20, wherein the at least one concentrating optic is a transparent sphere or a transparent hollow sphere and is composed of
glass, in particular, soda-lime glass or lead glass or borosilicate glass or optical glass;
organic glass, in particular, resins or polymers, or
a combination thereof,
the hollow sphere comprising one part and being associated with the mounting frame, the fluid filling the hollow sphere containing
water or ethanol or glycol, or
gel or,
a combination thereof,
or being composed thereof.

24. The absorber concentrator system or absorber module according to claim 20, wherein the absorption panel is preferably composed of:
steel or galvanized steel or stainless steel or aluminum or copper or other metals;
composites or other synthetic materials, or
glass or sintered materials,
a combination thereof,
and includes a coating, in particular, a coating of
Tinox or Ethaplus or other coatings,
a combination thereof
or is composed thereof.

25. The absorber concentrator system or absorber module according to claim 20, wherein the absorption panel comprises a heat-exchange system including at least one tube or tube system or a harp.

26. The absorber concentrator system or absorber module according to claim 20, wherein the hemispherical absorber support and the at least one absorption panel are pivotally mounted.

27. The photovoltaic concentrator system or absorber concentrator system according to claim 20, wherein the mounting frame includes a diode in the interior space.

28. The photovoltaic concentrator system or absorber concentrator system according to claim 20, wherein the photovoltaic concentrator system and/or absorber concentrator system comprises a Stirling engine.

29. The photovoltaic concentrator system or absorber concentrator system according to claim 20, further comprising a receiver.
